(19) United States
(12) Patent Application Publication
(10) Pub. No.: US 2023/0180560 A1
(43) Pub. Date: Jun. 8, 2023

(54) DISPLAYING DEVICE

(71) Applicants: SONY SEMICONDUCTOR SOLUTIONS CORPORATION, KANAGAWA (JP); SONY GROUP CORPORATION, TOKYO (JP)

(72) Inventors: SHUN ISHIJIMA, TOKYO (JP); TAKASHI TOYODA, KANAGAWA (JP); KEI KIMURA, TOKYO (JP)

(21) Appl. No.: 17/906,369

(22) PCT Filed: Mar. 4, 2021
(86) PCT No.: PCT/JP2021/008478

§ 371 Date: Sep. 15, 2022

(30) Foreign Application Priority Data
Mar. 27, 2020 (JP) 2020-058737

(51) Int. Cl. H10K 59/131

(52) U.S. Cl. CPC H10K 59/1315

(57) ABSTRACT

A displaying device that downsizes a displaying panel is provided.

A displaying device according to the present disclosure includes: a pixel array area that includes a plurality of pixels; a peripheral circuit provided outside the pixel array area; a printed circuit provided outside the pixel array area; and a wired power-source line that supplies a power source voltage to the peripheral circuit from the printed circuit through the pixel array area.

### TECHNICAL FIELD

Embodiments of the present disclosure relate to displaying devices.

### BACKGROUND ART

A displaying device, such as an organic electro-luminescence (EL) display, generally includes a peripheral circuit around a pixel array area. In this case, there is a problem that a wired power-source line from a flexible printed circuit (FPC) to the peripheral circuit increases the size of a displaying panel.

### CITATION LIST

### Patent Document

Patent Document 1: WO 2019/203027 A

### SUMMARY OF THE INVENTION

### Problems to be Solved by the Invention

Therefore, the present disclosure provides a displaying device that downsizes a displaying panel.

### Solutions to Problems

A displaying device according to a first aspect of the present disclosure includes: a pixel array area that includes a plurality of pixels; a peripheral circuit provided outside the pixel array area; a printed circuit provided outside the pixel array area; and a wired power-source line that supplies a power source voltage to the peripheral circuit from the printed circuit through the pixel array area. Therefore, the wired power-source line for the peripheral circuit is arranged in the pixel array area to downsize a displaying panel.

Furthermore, regarding the first aspect, the wired power-source line may supply the power source voltage to the pixels and the peripheral circuit. Therefore, the wired power-source line for the pixels is also used for the peripheral circuit to downsize a displaying panel.

Furthermore, the displaying device according to the first aspect may further include: a plurality of scan lines that extends in a first direction in the pixel array area; a plurality of signal lines that extends in a second direction in the pixel array area; a plurality of first wired power-source lines that extends in the first direction in the pixel array area; and a plurality of second wired power-source lines that extends in the second direction in the pixel array area, in which the wired power-source line that supplies the power source voltage to the peripheral circuit from the printed circuit may include the first wired power-source lines, the second wired power-source lines, or both the first and second wired power-source lines. Therefore, for example, the wired power-source line for the peripheral circuit is arranged along the scan lines or the signal lines.

Furthermore, regarding the first aspect, in a case where the wired power-source line that supplies the power source voltage to the peripheral circuit from the printed circuit includes the first wired power-source lines, a width of the first wired power-source lines may be thicker than a width of the second wired power-source lines. Therefore, the impedance of the wired power-source line for the peripheral circuit is decreased.

Furthermore, regarding the first aspect, in a case where the wired power-source line that supplies the power source voltage to the peripheral circuit from the printed circuit includes the second wired power-source lines, a width of the second wired power-source lines may be thicker than a width of the first wired power-source lines. Therefore, the impedance of the wired power-source line for the peripheral circuit is decreased.

Furthermore, regarding the first aspect, the pixels may be supplied with a power source voltage from the first and second wired power-source lines. Therefore, the wired power-source line for the pixels is also used for the peripheral circuit to downsize a displaying panel.

Furthermore, regarding the first aspect, each of the pixels may include N (N is an integer equal to or larger than two) subpixels, and the N subpixels may be supplied with a power source voltage from N of the second wired power-source lines. Therefore, the N subpixels of each of the pixels are supplied with the power source voltage from the different second wired power-source lines.

Furthermore, regarding the first aspect, a width of the first wired power-source lines may be N times a width of the second wired power-source lines. Therefore, the impedance of the first wired power-source lines is decreased.

Furthermore, the displaying device according to the first aspect may further include: a plurality of scan lines that extends in a first direction in the pixel array area; and a plurality of signal lines that extends in a second direction in the pixel array area, in which the printed circuit may be provided in the first direction of the pixel array area. Therefore, in a case where the printed circuit is arranged in the first direction of the pixel array area, a displaying panel is downsized.

Furthermore, regarding the first aspect, the wired power-source line may extend in the first direction in the pixel array area. Therefore, the wired power-source line extends in the first direction from the printed circuit.

Furthermore, regarding the first aspect, the peripheral circuit may include a writing and scanning unit electrically connected to the scan lines, and the writing and scanning unit may be supplied with the power source voltage from the wired power-source line. Therefore, the wired power-source line for the writing and scanning unit is arranged in the pixel array area to downsize a displaying panel.

Furthermore, regarding the first aspect, the writing and scanning unit and the printed circuit may be provided on opposite sides of the pixel array area. Therefore, for example, the writing and scanning unit far apart from a printed board is supplied with the power source voltage from the short wired power-source line.

Furthermore, regarding the first aspect, the peripheral circuit may further include a signal output unit electrically connected to the signal lines, and the signal output unit may be supplied with a power source voltage from another wired power-source line different from the wired power-source line. Therefore, for example, the writing and scanning unit and the signal output unit are supplied with the different power source voltages.

Furthermore, the displaying device according to the first aspect may further include: a plurality of scan lines that extends in a first direction in the pixel array area; and a plurality of signal lines that extends in a second direction in the pixel array area, in which the printed circuit may be provided in the second direction of the pixel array area. Therefore, in a case where the printed circuit is arranged in the second direction of the pixel array area, a displaying panel is downsized.

Furthermore, regarding the first aspect, the wired power-source line may extend in the second direction in the pixel array area. Therefore, the wired power-source line extends in the second direction from the printed circuit.

Furthermore, regarding the first aspect, the peripheral circuit may include a signal output unit electrically connected to the signal lines, and the signal output unit may be supplied with the power source voltage from the wired power-source line. Therefore, the wired power-source line for the signal output unit is arranged in the pixel array area to downsize a displaying panel.

Furthermore, regarding the first aspect, the signal output unit and the printed circuit may be provided on opposite sides of the pixel array area. Therefore, for example, the signal output unit far apart from a printed board is supplied with the power source voltage from the short wired power-source line.

Furthermore, regarding the first aspect, the peripheral circuit may further include a writing and scanning unit electrically connected to the scan lines, and the writing and scanning unit may be supplied with a power source voltage from another wired power-source line different from the wired power-source line. Therefore, for example, the writing and scanning unit and the signal output unit are supplied with the different power source voltages.

Furthermore, regarding the first aspect, the displaying device may be part of portable or wearable electronic equipment. Therefore, for example, the displaying panel is downsized for electronic equipment for which the downsizing of the displaying panel is much needed.

Furthermore, regarding the first aspect, the electronic equipment may include a camera or glasses that include the displaying device. Therefore, for example, the displaying panel is downsized for a camera or glasses for which the downsizing of the displaying panel is much needed.

### BRIEF DESCRIPTION OF DRAWINGS

FIG. 1 is a circuit diagram illustrating the configuration of a displaying device according to a first embodiment.

FIG. 2 is another circuit diagram illustrating the configuration of the displaying device according to the first embodiment.

FIG. 3 is a plan view illustrating the wired-line structure of the displaying device according to the first embodiment.

FIG. 4 is a plan view illustrating the wired-line structure of a displaying device according to a comparative example of the first embodiment.

FIG. 5 is a plan view illustrating the wired-line structure of the displaying device according to the first embodiment.

FIG. 6 is a plan view illustrating the wired-line structure of the displaying device according to the comparative example of the first embodiment.

FIG. 7 is a plan view illustrating the wired-line structure of a displaying device according to a second embodiment.

FIG. 8 is a plan view illustrating the wired-line structure of a displaying device according to a comparative example of the second embodiment.

FIG. 9 is a circuit diagram illustrating the configuration of a displaying device according to a third embodiment.

FIG. 10 is a circuit diagram illustrating the configuration of a displaying device according to a fourth embodiment.

FIG. 11 is a circuit diagram illustrating the configuration of a displaying device according to a fifth embodiment.

FIG. 12 is a circuit diagram illustrating the configuration of a displaying device according to a sixth embodiment.

FIG. 13 is a circuit diagram illustrating the configuration of a displaying device according to a seventh embodiment.

FIG. 14 is an exterior view illustrating the structure of electronic equipment according to an eighth embodiment.

FIG. 15 is an exterior view illustrating the structure of electronic equipment according to a ninth embodiment.

### MODE FOR CARRYING OUT THE INVENTION

Hereinafter, embodiments of the present disclosure will be described with reference to the drawings.

### First Embodiment

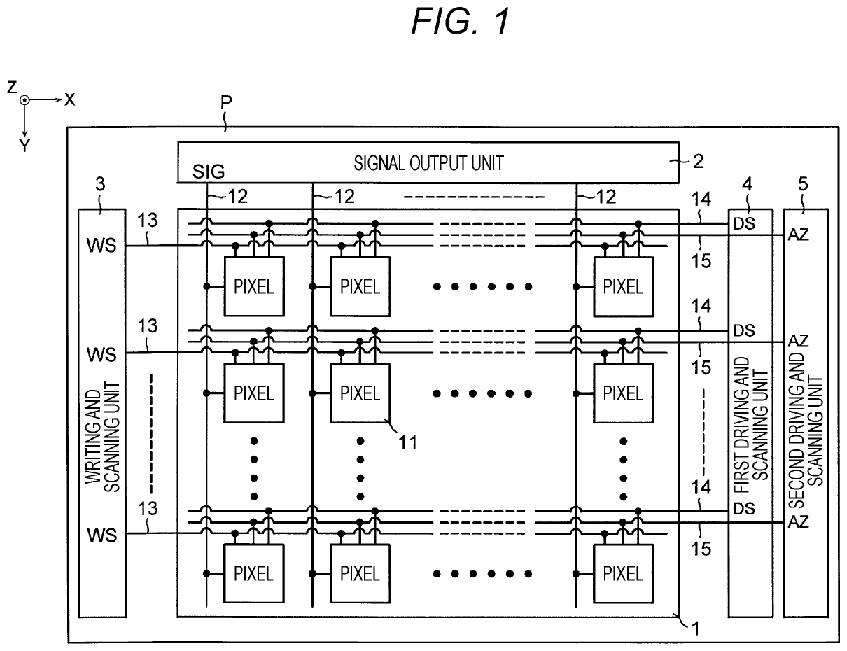

FIG. 1 is a circuit diagram illustrating the configuration of a displaying device according to a first embodiment. The displaying device according to the present embodiment is, for example, an organic electro-luminescence (EL) display of an active matrix organic light emitting diode (AM-OLED) type.

The displaying device according to the present embodiment includes a pixel array area 1, and a peripheral circuit provided outside the pixel array area 1. The peripheral circuit includes a signal output unit (Hdr) 2, a writing and scanning unit (Vdr) 3, a first driving and scanning unit 4, and a second driving and scanning unit 5. In FIG. 1, the pixel array area 1 is arranged on a displaying panel P, and the signal output unit 2, the writing and scanning unit 3, the first driving and scanning unit 4, and the second driving and scanning unit 5 are arranged around the pixel array area 1 on the displaying panel P. Note that part of the peripheral circuit may be arranged outside the displaying panel P.

FIG. 1 illustrates an X-axis, a Y-axis, and a Z-axis that are perpendicular to each other. In FIG. 1, an X-direction corresponds to a lateral direction (horizontal direction) of the paper surface, and a Y-direction corresponds to a vertical direction (perpendicular direction) of the paper surface. Furthermore, the X-direction and the Y-direction are parallel to the paper surface, and a Z-direction is perpendicular to the paper surface. ±X-directions are examples of a first direction according to the present disclosure. ±Y-directions are examples of a second direction according to the present disclosure.

The pixel array area 1 includes a plurality of pixels 11. These pixels 11 are arranged in a two-dimensional array in the pixel array area 1. In FIG. 1, the pixels 11 in m rows and n columns are near each other in the X-direction and the Y-direction (m and n are integers that are equal to or larger than two). As described later, each of the pixels 11 according to the present embodiment includes three subpixels for red (R), green (G), and blue (B).

The signal output unit 2 is electrically connected to a plurality of signal lines (SIG lines) 12 that extends in the Y-direction in the pixel array area 1. Each of the pixels 11 according to the present embodiment is electrically connected to any one of the n signal lines 12. The signal output unit 2 outputs an image signal Vsig to each of the pixels 11 through the corresponding signal line 12. Therefore, the image signal Vsig is written into each of the pixels 11. The signal output unit 2 according to the present embodiment is arranged in the −Y-direction of the pixel array area 1.

The writing and scanning unit 3 is electrically connected to a plurality of scan lines (WS lines) 12 that extends in the X-direction in the pixel array area 1. Each of the pixels 11 according to the present embodiment is electrically connected to any one of the m scan lines 13. When an image signal Vsig is written into each of the pixels 11, the writing and scanning unit 3 outputs a scan signal Vws into the pixels 11, row by row, in the pixel array area 1 from these scan lines 13. Therefore, the pixels 11 in the pixel array area 1 are sequentially scanned row by row, and the image signals Vsig are written into the pixels 11 selected by the scanning. The writing and scanning unit 3 according to the present embodiment is arranged in the −X-direction of the pixel array area 1.

The first driving and scanning unit 4 and the second driving and scanning unit 5 are electrically connected to a plurality of first drive lines (DS lines) 14 and a plurality of second drive lines (AZ lines) 15 that extend in the X-direction in the pixel array area 1, respectively. Each of the pixels 11 according to the present embodiment is electrically connected to any one of the m first drive lines 14 and any one of the m second drive lines 15. The first driving and scanning unit 4 supplies light emission control signals Vds to the first drive lines 14 synchronously with the scanning by the writing and scanning unit 3. Therefore, light emission and light non-emission of each of the pixels 11 are controlled. The second driving and scanning unit 5 supplies driving signals Vaz to the second drive lines 15 synchronously with the scanning by the writing and scanning unit 3. Therefore, each of the pixels 11 is controlled such that each of the pixels 11 does not emit light in a light non-emission period. The first driving and scanning unit 4 and the second driving and scanning unit 5 according to the present embodiment are arranged in the +X-direction of the pixel array area 1.

The displaying panel P includes, for example, a board. Examples of the board include an insulating transparent board, such as a glass board, and a semiconductor board, such as a silicon board. The displaying device according to the present embodiment includes the displaying panel P including a silicon board. The displaying panel P is a downsized microdisplay.

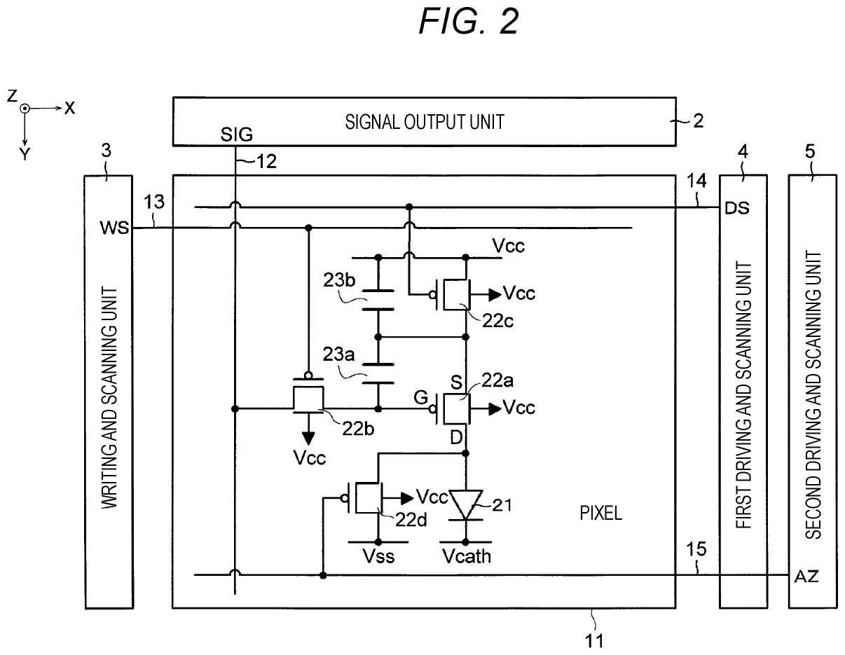

FIG. 2 is another circuit diagram illustrating the configuration of the displaying device according to the first embodiment.

Each of the pixels 11 according to the present embodiment has, for example, a circuit configuration illustrated in FIG. 2. The pixel 11 illustrated in FIG. 2 includes an organic EL element 21, four transistors 22a to 22d, and two capacitors 23a to 23b.

The organic EL element 21 is, for example, a light emitting diode, and functions as a light emitting unit of each of the pixels 11. A cathode terminal of the organic EL element 21 is connected to a cathode line that supplies a cathode electric potential Vcath. An anode terminal of the organic EL element 21 is connected to the transistors 22a and 22d.

The transistors 22a, 22b, 22c, and 22d function as a driving transistor, a writing transistor, a light emission control transistor, and a switching transistor, respectively. The transistor 22a includes a gate terminal connected to the transistor 22b and the capacitor 23a, a source terminal connected to the transistor 22c and the capacitors 23a and 23b, and a drain terminal connected to the organic EL element 21 and the transistor 22d. The transistor 22b includes a gate terminal connected to the scan line 13, and is arranged between the transistor 22a and the signal line 12. The transistor 22c includes a gate terminal connected to the first drive line 14, and is arranged between the transistor 22a and a voltage common collector (Vcc) wired power-source line. The transistor 22d includes a gate terminal connected to the second drive line 15, and is arranged between the transistor 22a and a voltage source supply (Vss) wired power-source line. Note that backgate terminals of the transistors 22a to 22d are connected to the Vcc wired power-source line.

In the pixel 11 illustrated in FIG. 2, the writing transistor 22b samples signal voltages Vsig supplied from the signal line 12 to supply the signal voltages Vsig to the gate terminal of the driving transistor 22a. The light emission control transistor 22c is driven by a light emission control signal Vds supplied from the first drive line 14 to control light emission and light non-emission of the organic EL element 21. The switching transistor 22d is driven by a driving signal Vaz supplied from the second drive line 15 to control the organic EL element 21 such that the organic EL element 21 does not emit light during a light non-emission period.

The capacitors 23a and 23b function as a maintaining capacity and an auxiliary capacity, respectively. These capacitors 23a and 23b are arranged between the gate terminal of the transistor 22a and the Vcc wired power-source line. Furthermore, a node between the capacitor 23a and the capacitor 23b is connected to the source terminal of the transistor 22a.

The capacitor (maintaining capacity) 23a maintains a signal voltage Vsig sampled by the writing transistor 22b. The driving transistor 22a supplies the organic EL element 21 with a driving electric current that corresponds to the voltage maintained by the capacitor 23a, to drive the organic EL element 21. The capacitor (auxiliary capacity) 23b has an effect of restricting the variation in the source voltage of the driving transistor 22a, and an effect of adjusting the voltage between the gate and the source of the driving transistor 22a, to a threshold voltage of the driving transistor 22a.

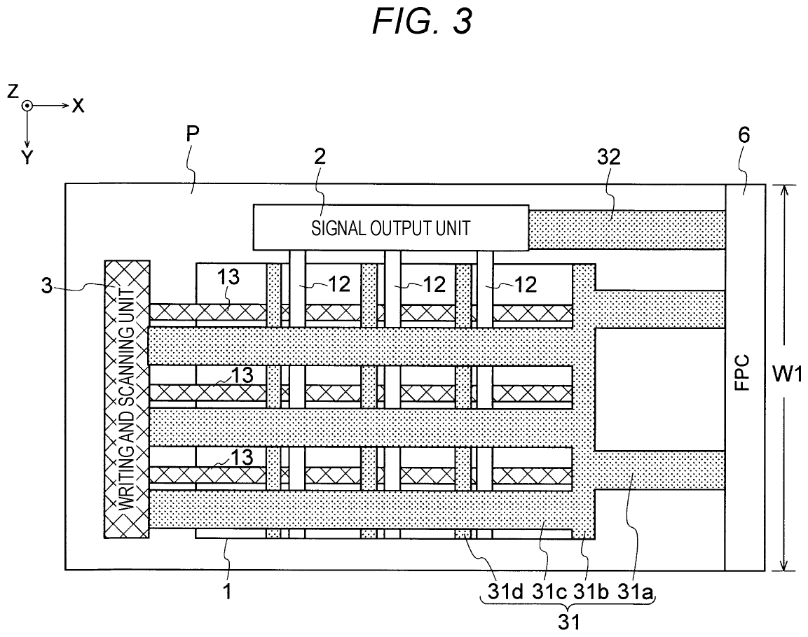

FIG. 3 is a plan view illustrating the wired-line structure of the displaying device according to the first embodiment.

The displaying device according to the present embodiment includes a flexible printed circuit (FPC) 6, a wired power-source line 31, and a wired power-source line 32, in addition to the components illustrated in FIGS. 1 and 2. The wired power-source line 31 includes a plurality of wired power-source lines 31a, a wired power-source line 31b, a plurality of wired power-source lines 31c, and a plurality of wired power-source lines 31d. The FPC 6 is an example of a printed circuit according to the present disclosure. FIG. 3 also illustrates the width W1, in the Y-direction, of the displaying panel P according to the present embodiment.

The wired power-source line 31 is provided to supply a power source voltage to each of the pixels 11 and the writing and scanning unit 3 from the FPC 6. Part of the wired power-source line 31 is provided in the pixel array area 1 on the displaying panel P. The rest of the wired power-source line 31 is provided outside the pixel array area 1 on the displaying panel P. The power source voltage supplied from the wired power-source line 31 may be a positive voltage or a negative voltage, or may be a zero voltage (ground voltage).

The wired power-source line 32 is provided to supply a power source voltage to the signal output unit 2 from the FPC 6. The whole wired power-source line 32 is provided outside the pixel array area 1 on the displaying panel P. The power source voltage supplied from the wired power-source line 32 may be a positive voltage or a negative voltage, or may be a zero voltage. The power source voltage from the wired power-source line 32 may be a voltage the same as or different from the power source voltage from the wired power-source line 31. In the present embodiment, however, the power source voltage from the wired power-source line 32 is a voltage different from the power source voltage from the wired power-source line 31.

The FPC 6 is provided to supply the power source voltages to, for example, the pixel array area 1 and the peripheral circuit. The FPC 6 is arranged outside the pixel array area 1. The FPC 6 according to the present embodiment is arranged in the +X-direction of the pixel array area 1. The FPC 6 and the writing and scanning unit 3 are arranged on opposite sides of the pixel array area 1. Therefore, the distance between the FPC 6 and the writing and scanning unit 3 is farther than the distance between the FPC 6 and the signal output unit 2.

The wired power-source lines 31a and the wired power-source line 31b are provided outside the pixel array area 1. The wired power-source lines 31a extend in the −X-direction from the FPC 6 toward the pixel array area 1. The wired power-source line 31b is electrically connected to the wired power-source lines 31a. The wired power-source line 31b extends in the Y-direction along an end, in the +X-direction, of the pixel array area 1.

The wired power-source lines 31c and the wired power-source lines 31d are provided in the pixel array area 1. The wired power-source lines 31c are electrically connected to the wired power-source line 31b. The wired power-source lines 31c extend in the −X-direction from the wired power-source line 31b to the writing and scanning unit 3 through the pixel array area 1. Therefore, the wired power-source line 31 according to the present embodiment supplies the power source voltage to the writing and scanning unit 3 from the FPC 6 through the wired power-source lines 31a, 31b, and 31c. The wired power-source lines 31d are electrically connected to the wired power-source lines 31c. The wired power-source lines 31d extend in the Y-direction in the pixel array area 1. The wired power-source line 31 according to the present embodiment supplies the power source voltage to each of the pixels 11 from the FPC 6 through the wired power-source lines 31a, 31b, 31c, and 31d. The wired power-source lines 31c are an example of first wired power-source lines according to the present disclosure. The wired power-source lines 31d are an example of second wired power-source lines according to the present disclosure.

Note that the wired power-source lines 31c according to the present embodiment are arranged at positions higher than the wired power-source lines 31d, and cross over the wired power-source lines 31d such that the wired power-source lines 31c according to the present embodiment do not directly touch the wired power-source lines 31d. In the present embodiment, via plugs are arranged at positions where the wired power-source lines 31c and the wired power-source lines 31d cross over each other in the Z-direction. Specifically, the plurality of via plugs is arranged on each of the wired power-source lines 31d, and the plurality of wired power-source lines 31c is arranged on these via plugs. Therefore, each of the wired power-source lines 31c and each of the wired power-source lines 31d are electrically connected to each other by one of the via plugs. Note that the width (dimension in the Y-direction) of each of the wired power-source lines 31c according to the present embodiment is set thicker than the width (dimension in the X-direction) of each of the wired power-source lines 31d.

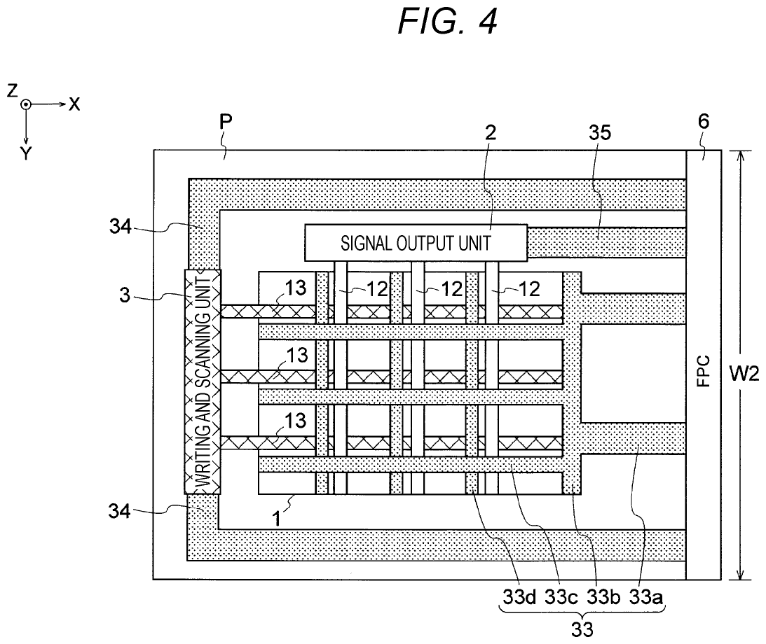

FIG. 4 is a plan view illustrating the wired-line structure of a displaying device according to a comparative example of the first embodiment.

In the present comparative example, the wired power-source line 31 and the wired power-source line 32 that are illustrated in FIG. 3 are replaced with a wired power-source line 33, a plurality of wired power-source lines 34, and a wired power-source line 35. The wired power-source line 33 includes a plurality of wired power-source lines 33a, a wired power-source line 33b, a plurality of wired power-source lines 33c, and a plurality of wired power-source lines 33d. FIG. 4 also illustrates the width W2, in a Y-direction, of a displaying panel P according to the present comparative example.

The structures and functions of the wired power-source lines 33a, 33b, 33c, and 33d according to the present comparative example are substantially similar to the structures and functions of the wired power-source lines 31a, 31b, 31c, and 31d according to the first embodiment, respectively. However, the wired power-source lines 33c do not extend to a writing and scanning unit 3, and are not electrically connected to the writing and scanning unit 3. Therefore, the wired power-source line 33 supplies a power source voltage to only each pixel 11, and does not supply the power source voltage to the writing and scanning unit 3. In the present comparative example, the wired power-source lines 34 supply a power source voltage to the writing and scanning unit 3, and the wired power-source line 35 supplies a power source voltage to a signal output unit 2.

Since the wired power-source lines 34 according to the present comparative example are separated from the wired power-source line 33, the wired power-source lines 34 according to the present comparative example do not pass through a pixel array area 1. The reason is that in the pixel array area 1, there is not a space where both the wired power-source lines 33 and 34 can be arranged. Therefore, the wired power-source lines 34 are arranged around the pixel array area 1 on the displaying panel P. However, arranging the wired power-source lines 34 around the pixel array area 1 generates the necessity of widening the area of a bezel of the displaying panel P, that is to say, the area around the pixel array area 1 on the displaying panel P, and generates the necessity of increasing the size of the displaying panel P. Specifically, the necessity of increasing the width W2, in the Y-direction, of the displaying panel P is generated. Which is not preferable in a case where the displaying panel P needs to be downsized.

Furthermore, the writing and scanning unit 3 according to the present comparative example is arranged at a position far from an FPC 6, similarly to the case of the first embodiment. Therefore, arranging the wired power-source lines 34 around the pixel array area 1 lengthens the wired power-source lines 34. As a result, the electrical resistance (impedance) of the wired power-source lines 34 increases, and a voltage drop at the wired power-source lines 34 increases. Therefore, there is a possibility that shading deterioration and the generation of crosstalk degrade the image quality.

On the other hand, the wired power-source line 31 according to the first embodiment (FIG. 3) extends to the writing and scanning unit 3 through the pixel array area 1, and is electrically connected to the writing and scanning unit 3. Therefore, the area of a bezel of the displaying panel P, that is to say, the area around the pixel array area 1 on the displaying panel P is narrowed. Therefore, according to the present embodiment, the displaying panel P is downsized, and the width W1, in the Y-direction, of the displaying panel P is decreased. The width W1 according to the present embodiment is smaller than the width W2 according to the comparative example described above. Since the wired power-source line 31 according to the present embodiment is shared by the pixels 11 and the writing and scanning unit 3, the wired power-source line 31 according to the present embodiment is arranged in the pixel array area 1.

Furthermore, the distance from the FPC 6 to the writing and scanning unit 3 along the wired power-source line 31 according to the present embodiment is made shorter than the distance from the FPC 6 to the writing and scanning unit 3 along the wired power-source lines 34 according to the comparative example described above. Therefore, the electrical resistance (impedance) between the FPC 6 and the writing and scanning unit 3 in the wired power-source line 31 according to the present embodiment is made lower than the electrical resistance (impedance) between the FPC 6 and the writing and scanning unit 3 in the wired power-source lines 34 according to the comparative example described above. Therefore, according to the present embodiment, a voltage drop between the FPC 6 and the writing and scanning unit 3 is decreased.

Note that in the present embodiment, not only the wired power-source lines 31c are electrically connected to the writing and scanning unit 3, but also the wired power-source lines 31d may be electrically connected to the signal output unit 2. Therefore, the wired power-source lines 31a to 31d supply a power source voltage to each of the pixels 11, the writing and scanning unit 3, and the signal output unit 2. Furthermore, a configuration in which the wired power-source line 32 is not provided is adopted. In a case illustrated in FIG. 3, however, the wired power-source line 32 is short, and the wired power-source line 32 is arranged without increasing the size of the displaying panel P. Therefore, the wired power-source line 32 according to the present embodiment is separated from the wired power-source line 31. Note that the wired power-source line 31 according to the present embodiment may supply the power source voltage to a circuit included in the peripheral circuit except the writing and scanning unit 3. For example, the wired power-source line 31 according to the present embodiment may supply the power source voltage to a timing controller for synchronizing an operation of the signal output unit 2 and an operation of the writing and scanning unit 3.

Furthermore, the wired power-source line 31 according to the present embodiment may be used as, for example, the Vcc wired power-source line or the Vss wired power-source line illustrated in FIG. 2. The electrical resistance of the wired power-source line 31 is decreased by including, for example, aluminum in the wired power-source line 31.

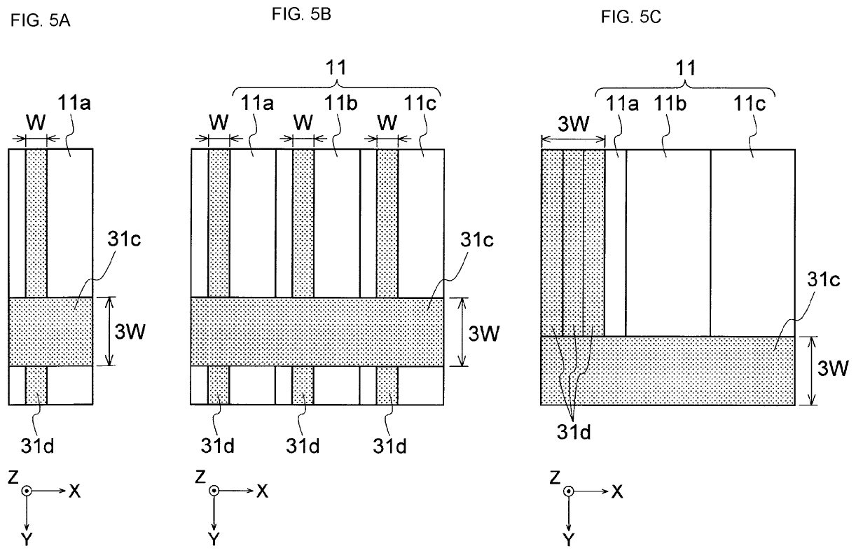

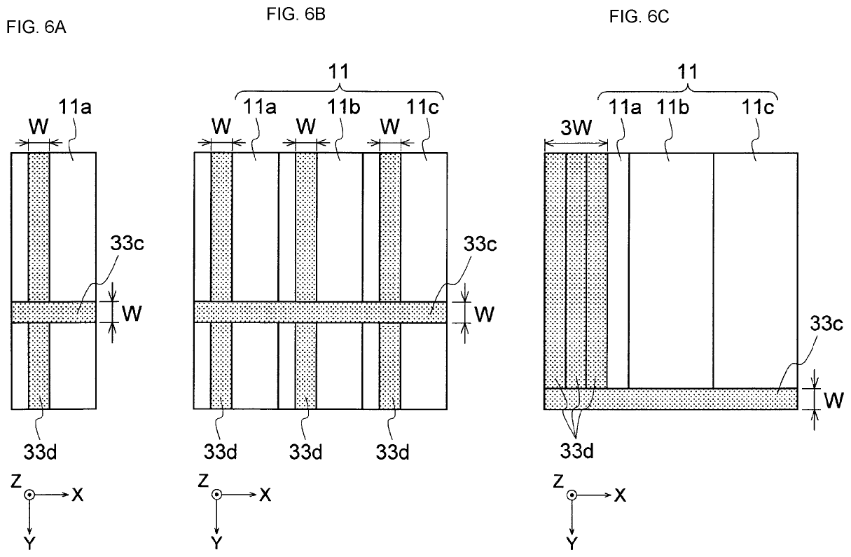

Furthermore, since the wired power-source lines 31c according to the present embodiment are used to supply the power source voltage to the writing and scanning unit 3, the width of the wired power-source lines 31c according to the present embodiment is set thicker than the width of the wired power-source lines 31d according to the present embodiment, and the widths of the wired power-source lines 33c and 33d according to the comparative example described above. Further details of these widths will be described later with reference to FIGS. 5 and 6.

FIG. 5 is a plan view illustrating the wired-line structure of the displaying device according to the first embodiment.

A of FIG. 5 illustrates one subpixel 11a included in one of the pixels 11 according to the present embodiment. As illustrated in A of FIG. 5, in the one subpixel 11a, the wired power-source line 31 according to the present embodiment includes one of the wired power-source lines 31c extending in the X-direction, and one of the wired power-source lines 31d extending in the Y-direction.

B of FIG. 5 illustrates one of the pixels 11 according to the present embodiment. Each of the pixels 11 according to the present embodiment includes N (N is an integer equal to or larger than two) subpixels. For example, each of the pixels 11 according to the present embodiment includes three subpixels 11a, 11b, and 11c, as illustrated in B of FIG. 5. The subpixels 11a, 11b, and 11c according to the present embodiment are provided for red (R), green (G), and blue (B), respectively. In the present embodiment, the shape of each of the pixels 11 is square, and the three subpixels 11a to 11c align in the X-direction. Therefore, the shape of each of the subpixels 11a to 11c according to the present embodiment is a rectangle having two shorter sides extending in the X-direction, and two longer sides extending in the Y-direction.

As illustrated in B of FIG. 5, in one of the pixels 11, the wired power-source line 31 according to the present embodiment includes one of the wired power-source lines 31c, and some of the wired power-source lines 31d the number of which is the same as the number of the subpixels 11a to 11c (herein, three). Therefore, in each of the pixels 11, the three subpixels 11a to 11c and the three wired power-source lines 31d have a one-to-one correspondence. In the present embodiment, the power source voltage is supplied to these three subpixels 11a to 11c from these three wired power-source lines 31d.

As described above, the shape of each of the pixels 11 according to the present embodiment is square. On the other hand, each of the pixels 11 according to the present embodiment is supplied with the power source voltage from one of the wired power-source lines 31c and three of the wired power-source lines 31d. Therefore, in the pixel array area 1, the number of the wired power-source lines 31d is large, and the density of the wired power-source lines 31d is likely to be high, while the number of the wired power-source lines 31c is small, and the density of the wired power-source lines 31c is likely to be low. Therefore, in the present embodiment, it is difficult to make the wired power-source lines 31d thick, but it is easy to make the wired power-source lines 31c thick.

Which is a preferable fact for the present embodiment. The reason is that since the wired power-source lines 31c according to the present embodiment are used to supply the power source voltage to the writing and scanning unit 3, it is preferable that the width of the wired power-source lines 31c according to the present embodiment is made thick. Therefore, the width of each of the wired power-source lines 31c according to the present embodiment is set N times (herein, three times) the width of each of the wired power-source lines 31d. B of FIG. 5 illustrates “W” that is the width of each of the wired power-source lines 31d, and “3W” that is the width of each of the wired power-source lines 31c.

For a comparison of the width of the wired power-source lines 31c and the width of the wired power-source lines 31d, C of FIG. 5 illustrates one of the wired power-source lines 31c in the −X-direction, and illustrates three of the wired power-source lines 31d gathered, in the −Y-direction. As illustrated in C of FIG. 5, each of the pixels 11 according to the present embodiment is supplied with the power source voltage from one of the wired power-source lines 31c having the width of “3W” and three of the wired power-source lines 31d having the total width of “3W”. Therefore, in the pixel array area 1 according to the present embodiment, the density of the wired power-source lines 31c is approximately the same as the density of the wired power-source lines 31d. As described above, according to the present embodiment, an advantage that it is easy to thicken the width of the wired power-source lines 31c is obtained.

Note that the displaying device according to the present embodiment may be a monochrome displaying device or a color displaying device. Herein, however, the displaying device according to the present embodiment is a color displaying device. In a case where the displaying device according to the present embodiment is a color displaying device in this way, the configuration of the one pixel 11 illustrated in FIG. 2 exactly corresponds to the configuration of the one subpixel 11a, 11b, or 11c. On the other hand, in a case where the displaying device according to the present embodiment is a monochrome displaying device, the configuration of the one pixel 11 illustrated in FIG. 2 actually corresponds to the configuration of the one pixel 11.

FIG. 6 is a plan view illustrating the wired-line structure of the displaying device according to the comparative example of the first embodiment.

A, B, and C of FIG. 6 correspond to A, B, and C of FIG. 5, respectively. In the present comparative example, the width of each of the wired power-source lines 33d is “W”, and the width of each of the wired power-source lines 33c is also “W”. If the wired power-source lines 33c are electrically connected to the writing and scanning unit 3, there is a possibility that the high electrical resistance of the wired power-source lines 33c becomes a problem. On the other hand, according to the present embodiment, the width of the wired power-source lines 31c is thickened to restrict the problem.

As described above, the displaying device according to the present embodiment includes the wired power-source line 31 that supplies the power source voltage to the writing and scanning unit 3 from the FPC 6 through the inside of the pixel array area 1. Therefore, according to the present embodiment, the displaying panel P is downsized.

### Second Embodiment

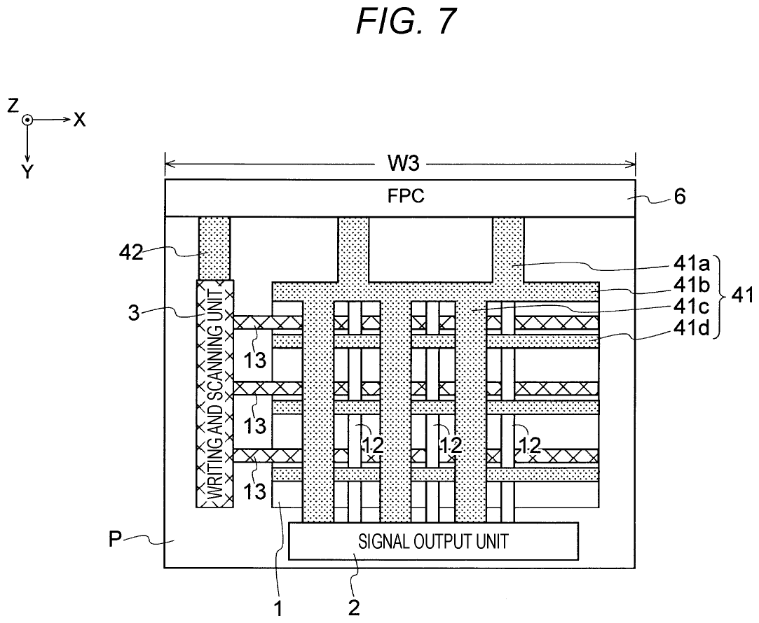

FIG. 7 is a plan view illustrating the wired-line structure of a displaying device according to a second embodiment.

In the present embodiment, the wired power-source line 31 and the wired power-source line 32 that are illustrated in FIG. 3 are replaced with a wired power-source line 41, and a wired power-source line 42. The wired power-source line 41 includes a plurality of wired power-source lines 41a, a wired power-source line 41b, a plurality of wired power-source lines 41c, and a plurality of wired power-source lines 41d. FIG. 7 also illustrates the width W3, in an X-direction, of a displaying panel P according to the present embodiment.

In the present embodiment, a signal output unit 2 is arranged in a +Y-direction of a pixel array area 1, and an FPC 6 is arranged in a −Y-direction of the pixel array area 1. Therefore, the FPC 6 and the signal output unit 2 are arranged on opposite sides of the pixel array area 1. Therefore, the distance between the FPC 6 and the signal output unit 2 is farther than the distance between the FPC 6 and a writing and scanning unit 3.

The wired power-source line 41 is provided to supply a power source voltage to each pixel 11 and the signal output unit 2 from the FPC 6. Part of the wired power-source line 41 is provided in the pixel array area 1 on the displaying panel P. The rest of the wired power-source line 41 is provided outside the pixel array area 1 on the displaying panel P. The power source voltage supplied from the wired power-source line 41 may be a positive voltage or a negative voltage, or may be a zero voltage (ground voltage).

The wired power-source line 42 is provided to supply a power source voltage to the writing and scanning unit 3 from the FPC 6. The whole wired power-source line 42 is provided outside the pixel array area 1 on the displaying panel P. The power source voltage supplied from the wired power-source line 42 may be a positive voltage or a negative voltage, or may be a zero voltage. The power source voltage from the wired power-source line 42 may be a voltage the same as or different from the power source voltage from the wired power-source line 41. In the present embodiment, however, the power source voltage from the wired power-source line 42 is a voltage different from the power source voltage from the wired power-source line 41.

The wired power-source lines 41a and the wired power-source line 41b are provided outside the pixel array area 1. The wired power-source lines 41a extend in the +Y-direction from the FPC 6 toward the pixel array area 1. The wired power-source line 41b is electrically connected to the wired power-source lines 41a. The wired power-source line 41b extends in the X-direction along an end, in the −Y-direction, of the pixel array area 1.

The wired power-source lines 41c and the wired power-source lines 41d are provided in the pixel array area 1. The wired power-source lines 41c are electrically connected to the wired power-source line 41b. The wired power-source lines 41c extend in the +Y-direction from the wired power-source line 41b to the signal output unit 2 through the pixel array area 1. Therefore, the wired power-source line 41 according to the present embodiment supplies the power source voltage to the signal output unit 2 from the FPC 6 through the wired power-source lines 41a, 41b, and 41c. The wired power-source lines 41d are electrically connected to the wired power-source lines 41c. The wired power-source lines 41d extend in the X-direction in the pixel array area 1. The wired power-source line 41 according to the present embodiment supplies the power source voltage to each of the pixels 11 from the FPC 6 through the wired power-source lines 41a, 41b, 41c, and 41d. The wired power-source lines 41d are an example of first wired power-source lines according to the present disclosure. The wired power-source lines 41c are an example of second wired power-source lines according to the present disclosure.

Note that the wired power-source lines 41c according to the present embodiment are arranged at positions higher than the wired power-source lines 41d, and cross over the wired power-source lines 41d such that the wired power-source lines 41c according to the present embodiment do not directly touch the wired power-source lines 41d. In the present embodiment, via plugs are arranged at positions where the wired power-source lines 41c and the wired power-source lines 41d cross over each other in a Z-direction. Specifically, the plurality of via plugs is arranged on each of the wired power-source lines 41d, and the plurality of wired power-source lines 41c is arranged on these via plugs. Therefore, each of the wired power-source lines 41c and each of the wired power-source lines 41d are electrically connected to each other by one of the via plugs. Note that the width (dimension in the X-direction) of each of the wired power-source lines 41c according to the present embodiment is set thicker than the width (dimension in the Y-direction) of each of the wired power-source lines 41d.

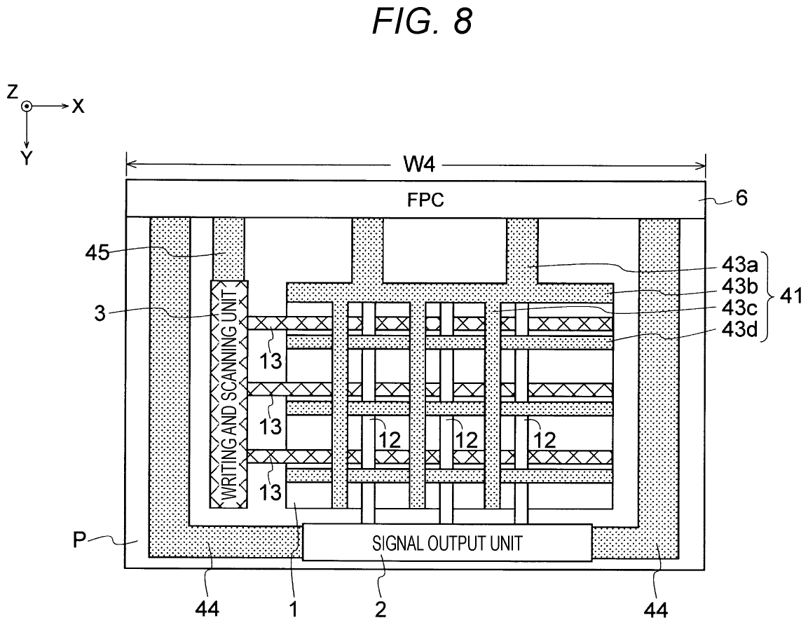

FIG. 8 is a plan view illustrating the wired-line structure of a displaying device according to a comparative example of the second embodiment.

In the present comparative example, the wired power-source line 41 and the wired power-source line 42 that are illustrated in FIG. 7 are replaced with a wired power-source line 43, a plurality of wired power-source lines 44, and a wired power-source line 45. The wired power-source line 43 includes a plurality of wired power-source lines 43a, a wired power-source line 43b, a plurality of wired power-source lines 43c, and a plurality of wired power-source lines 43d. FIG. 4 also illustrates the width W4, in an X-direction, of a displaying panel P according to the present comparative example.

The structures and functions of the wired power-source lines 43a, 43b, 43c, and 43d according to the present comparative example are substantially similar to the structures and functions of the wired power-source lines 41a, 41b, 41c, and 41d according to the second embodiment, respectively. However, the wired power-source lines 43c do not extend to a signal output unit 2, and are not electrically connected to the signal output unit 2. Therefore, the wired power-source line 43 supplies a power source voltage to only each pixel 11, and does not supply the power source voltage to the signal output unit 2. In the present comparative example, the wired power-source lines 44 supply a power source voltage to the signal output unit 2, and the wired power-source line 45 supplies a power source voltage to a writing and scanning unit 3.

Since the wired power-source lines 44 according to the present comparative example are separated from the wired power-source line 43, the wired power-source lines 44 according to the present comparative example do not pass through a pixel array area 1. The reason is that in the pixel array area 1, there is not a space where both the wired power-source lines 43 and 44 can be arranged. Therefore, the wired power-source lines 44 are arranged around the pixel array area 1 on the displaying panel P. However, arranging the wired power-source lines 44 around the pixel array area 1 generates the necessity of widening the area of a bezel of the displaying panel P, that is to say, the area around the pixel array area 1 on the displaying panel P, and generates the necessity of increasing the size of the displaying panel P. Specifically, the necessity of increasing the width W4, in the X-direction, of the displaying panel P is generated. Which is not preferable in a case where the displaying panel P needs to be downsized.

Furthermore, the signal output unit 2 according to the present comparative example is arranged at a position far from an FPC 6, similarly to the case of the second embodiment. Therefore, arranging the wired power-source lines 44 around the pixel array area 1 lengthens the wired power-source lines 44. As a result, the electrical resistance (impedance) of the wired power-source lines 44 increases, and a voltage drop at the wired power-source lines 44 increases. Therefore, there is a possibility that shading deterioration and the generation of crosstalk degrade the image quality.

On the other hand, the wired power-source line 41 according to the second embodiment (FIG. 7) extends to the signal output unit 2 through the pixel array area 1, and is electrically connected to the signal output unit 2. Therefore, the area of a bezel of the displaying panel P, that is to say, the area around the pixel array area 1 on the displaying panel P is narrowed. Therefore, according to the present embodiment, the displaying panel P is downsized, and the width W2, in the X-direction, of the displaying panel P is decreased. The width W3 according to the present embodiment is smaller than the width W4 according to the comparative example described above. Since the wired power-source line 41 according to the present embodiment is shared by the pixels 11 and the signal output unit 2, the wired power-source line 41 according to the present embodiment is arranged in the pixel array area 1.

Furthermore, the distance from the FPC 6 to the signal output unit 2 along the wired power-source line 41 according to the present embodiment is made shorter than the distance from the FPC 6 to the signal output unit 2 along the wired power-source lines 44 according to the comparative example described above. Therefore, the electrical resistance (impedance) between the FPC 6 and the signal output unit 2 in the wired power-source line 41 according to the present embodiment is made lower than the electrical resistance (impedance) between the FPC 6 and the signal output unit 2 in the wired power-source lines 44 according to the comparative example described above. Therefore, according to the present embodiment, a voltage drop between the FPC 6 and the signal output unit 2 is decreased.

Note that in the present embodiment, not only the wired power-source lines 41c are electrically connected to the signal output unit 2, but also the wired power-source lines 41d may be electrically connected to the writing and scanning unit 3. Therefore, the wired power-source lines 41a to 41d supply a power source voltage to each of the pixels 11, the signal output unit 2, and the writing and scanning unit 3. Furthermore, a configuration in which the wired power-source line 42 is not provided is adopted. In a case illustrated in FIG. 7, however, the wired power-source line 42 is short, and the wired power-source line 42 is arranged without increasing the size of the displaying panel P. Therefore, the wired power-source line 42 according to the present embodiment is separated from the wired power-source line 41. Note that the wired power-source line 41 according to the present embodiment may supply the power source voltage to a circuit included in the peripheral circuit except the signal output unit 2. For example, the wired power-source line 41 according to the present embodiment may supply the power source voltage to a timing controller for synchronizing an operation of the writing and scanning unit 3 and an operation of the signal output unit 2.

Furthermore, the wired power-source line 41 according to the present embodiment may be used as, for example, the Vcc wired power-source line or the Vss wired power-source line illustrated in FIG. 2. The electrical resistance of the wired power-source line 41 is decreased by including, for example, aluminum in the wired power-source line 41.

Furthermore, since the wired power-source lines 41c according to the present embodiment are used to supply the power source voltage to the signal output unit 2, the width of the wired power-source lines 41c according to the present embodiment is set thicker than the width of the wired power-source lines 41d according to the present embodiment, and the widths of the wired power-source lines 43c and 43d according to the comparative example described above. Which is similar to the wired power-source lines 31 and 33 of the first embodiment and the comparative example of the first embodiment.

Each of the pixels 11 according to the present embodiment includes N subpixels, similar to each of the pixels 11 according to the first embodiment. For example, each of the pixels 11 according to the present embodiment includes three subpixels 11a, 11b, and 11c, as illustrated in B of FIG. 5. In the present embodiment also, the shape of each of the pixels 11 is square, and the three subpixels 11a to 11c align in the X-direction. Therefore, the shape of each of the subpixels 11a to 11c according to the present embodiment is a rectangle having two shorter sides extending in the X-direction, and two longer sides extending in the Y-direction.

Note that the displaying device according to the present embodiment may be a monochrome displaying device or a color displaying device. Herein, however, the displaying device according to the present embodiment is a color displaying device. In a case where the displaying device according to the present embodiment is a color displaying device in this way, the configuration of the one pixel 11 illustrated in FIG. 2 exactly corresponds to the configuration of the one subpixel 11a, 11b, or 11c. On the other hand, in a case where the displaying device according to the present embodiment is a monochrome displaying device, the configuration of the one pixel 11 illustrated in FIG. 2 actually corresponds to the configuration of the one pixel 11.

As described above, the displaying device according to the present embodiment includes the wired power-source line 41 that supplies the power source voltage to the signal output unit 2 from the FPC 6 through the inside of the pixel array area 1. Therefore, according to the present embodiment, the displaying panel P is downsized.

Here, the first embodiment and the second embodiment are compared to each other. The configuration of the displaying device according to the first embodiment is adopted in, for example, a case where it is preferable that the FPC 6 is arranged in the +X-direction or the −X-direction of the displaying panel P. On the other hand, the configuration of the displaying device according to the second embodiment is adopted in, for example, a case where it is preferable that the FPC 6 is arranged in the +Y-direction or the −Y-direction of the displaying panel P. In any one of the first and second embodiments, the three subpixels 11a to 11c included in each of the pixels 11 align in the X-direction. Therefore, the first embodiment has an advantage that thickening the width of the wired power-source lines 31c in the first embodiment is easier than thickening the width of the wired power-source lines 41c in the second embodiment. The reason is that there is larger room of the space in the pixel array area 1 in a case where the plurality of thick wired power-source lines 31c extending in the X-direction is arranged than in a case where the plurality of thick wired power-source lines 41c extending in the Y-direction is arranged.

### Third to Seventh Embodiments

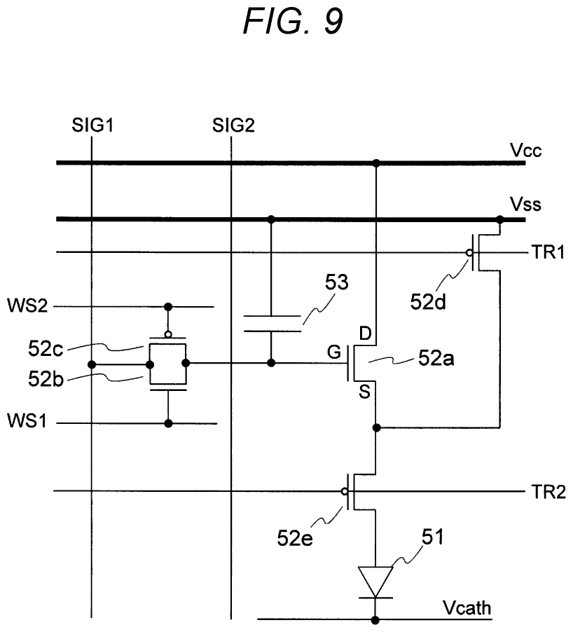

The circuit configuration of the pixel 11 illustrated in FIG. 2 may be replaced with, for example, the circuit configuration of a pixel 11 illustrated in any one of FIGS. 9 to 13. Hereinafter, the configuration of each of the pixels 11 of displaying devices according to third to seventh embodiments will be described with reference to FIGS. 9 to 13. Note that in a case where the displaying devices according to these embodiments are color displaying devices, the configuration of the one pixel 11 illustrated in FIGS. 9 to 13 exactly corresponds to the configuration of one subpixel 11a, 11b, or 11c.

FIG. 9 is a circuit diagram illustrating the configuration of a displaying device according to the third embodiment.

Each pixel 11 according to the present embodiment has, for example, a circuit configuration illustrated in FIG. 9, and includes an organic EL element 51, five transistors 52a to 52e, and one capacitor 53. The functions of the organic EL element 51, the transistors 52a to 52e, and the capacitor 53 according to the present embodiment are substantially similar to the functions of the organic EL element 21, the transistors 22a to 22d, and the capacitors 23a to 23b according to the first embodiment.

FIG. 9 illustrates two signal lines SIG1 to SIG2, two scan lines WS1 to WS2, two control lines TR1 to TR2, a Vcc wired power-source line, a Vss wired power-source line, and a cathode line that supplies a cathode electric potential Vcath to the organic EL element 51. The signal line SIG1 supplies signals to the pixel 11 illustrated in FIG. 9. The signal line SIG2 supplies signals to the pixel 11 next to the pixel 11 illustrated in FIG. 9. The scan lines WS1 to WS2 are connected to gate terminals of the transistors 52b and 52c, respectively. The control lines TR1 to TR2 are connected to gate terminals of the transistors 52d and 52e, respectively. The Vcc wired power-source line is connected to, for example, a drain terminal of the transistor 52a. The Vss wired power-source line is connected to, for example, the capacitor 53.

In a case where the circuit configuration of the pixels 11 according to the present embodiment is applied to the first or second embodiment, the wired power-source line 31 or 41 may be used as, for example, the Vcc wired power-source line or the Vss wired power-source line illustrated in FIG. 9.

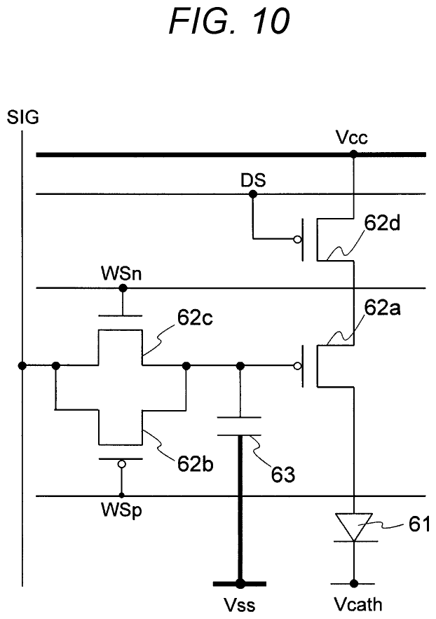

FIG. 10 is a circuit diagram illustrating the configuration of a displaying device according to the fourth embodiment.

Each pixel 11 according to the present embodiment has, for example, a circuit configuration illustrated in FIG. 10, and includes an organic EL element 61, four transistors 62a to 62d, and one capacitor 63. The functions of the organic EL element 61, the transistors 62a to 62d, and the capacitor 63 according to the present embodiment are substantially similar to the functions of the organic EL element 21, the transistors 22a to 22d, and the capacitors 23a to 23b according to the first embodiment.

FIG. 10 illustrates a signal line SIG, two scan lines WSp to WSn, a drive line DS, a Vcc wired power-source line, a Vss wired power-source line, and a cathode line that supplies a cathode electric potential Vcath to the organic EL element 61. The signal line SIG supplies signals to the pixel 11 illustrated in FIG. 10. The scan lines WSp to WSn and the drive line DS are connected to gate terminals of the transistors 62b, 62c, and 62d, respectively. The Vcc wired power-source line is connected to, for example, the transistor 62d. The Vss wired power-source line is connected to, for example, the capacitor 63.

In a case where the circuit configuration of the pixels 11 according to the present embodiment is applied to the first or second embodiment, the wired power-source line 31 or 41 may be used as, for example, the Vss wired power-source line illustrated in FIG. 10. Note that the Vcc wired power-source line according to the present embodiment is not applied to the wired power-source lines 31 and 41 because the Vcc wired power-source line according to the present embodiment is used as a control line.

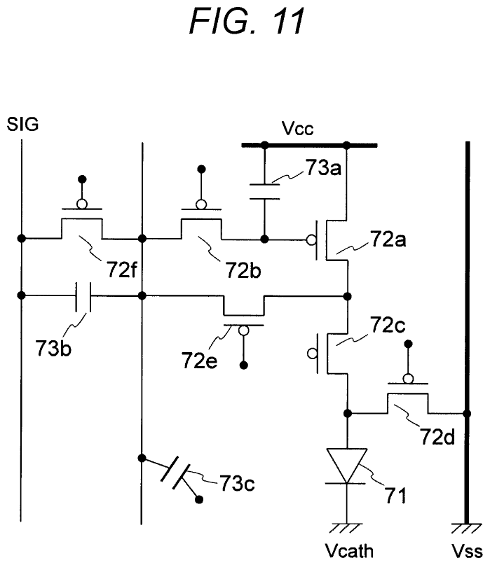

FIG. 11 is a circuit diagram illustrating the configuration of a displaying device according to the fifth embodiment.

Each pixel 11 according to the present embodiment has, for example, a circuit configuration illustrated in FIG. 11, and includes an organic EL element 71, six transistors 72a to 72f, and three capacitors 73a to 73c. The functions of the organic EL element 71, the transistors 72a to 72f, and the capacitors 73a to 73c according to the present embodiment are substantially similar to the functions of the organic EL element 21, the transistors 22a to 22d, and the capacitors 23a to 23b according to the first embodiment.

FIG. 11 illustrates a signal line SIG, a Vcc wired power-source line, a Vss wired power-source line, and a cathode line that supplies a cathode electric potential Vcath to the organic EL element 71. The signal line SIG supplies signals to the pixel 11 illustrated in FIG. 11. The Vcc wired power-source line is connected to, for example, the transistor 72a and the capacitor 73a. The Vss wired power-source line is connected to, for example, the transistor 72d.

In a case where the circuit configuration of the pixels 11 according to the present embodiment is applied to the first or second embodiment, the wired power-source line 31 or 41 may be used as, for example, the Vcc wired power-source line or the Vss wired power-source line illustrated in FIG. 11.

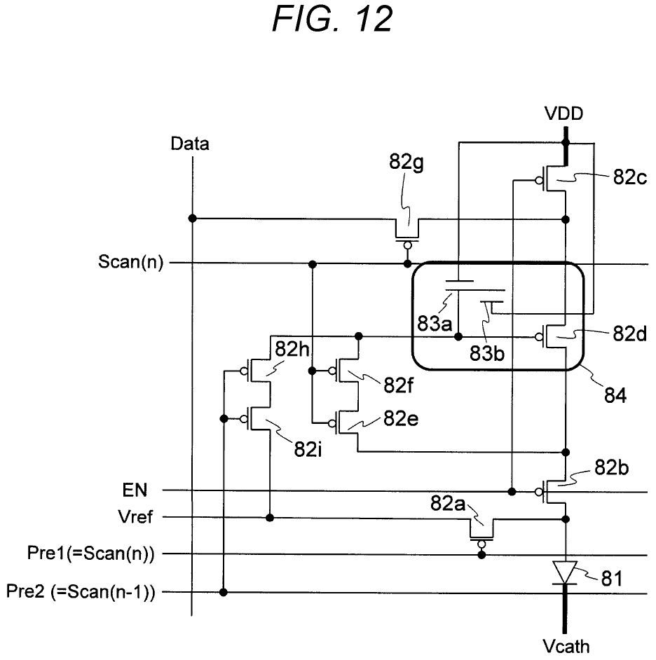

FIG. 12 is a circuit diagram illustrating the configuration of a displaying device according to the sixth embodiment.

Each pixel 11 according to the present embodiment has, for example, a circuit configuration illustrated in FIG. 12, and includes an organic EL element 81, nine transistors 82a to 82i, and two capacitors 83a to 83b. The functions of the organic EL element 81, the transistors 82a to 82i, and the capacitors 83a to 83b according to the present embodiment are substantially similar to the functions of the organic EL element 21, the transistors 22a to 22d, and the capacitors 23a to 23b according to the first embodiment. The transistor 82a is connected to the capacitors 83a to 83b in an extent indicated by reference sign 84.

FIG. 12 illustrates a signal line Data, a scan line Scan(n), an enable line EN, a voltage device drain (VDD) wired power-source line, a reference line that supplies a reference voltage Vref, a cathode line that supplies a cathode electric potential Vcath to the organic EL element 81, and the like. The signal line Data supplies signals to the pixel 11 illustrated in FIG. 12. The scan line Scan(n) is connected to gate terminals of the transistors 82e, 82f, and 82g. The VDD wired power-source line is connected to, for example, the transistor 82c. Note that the cathode line according to the present embodiment corresponds to a VSS wired power-source line.

In a case where the circuit configuration of the pixels 11 according to the present embodiment is applied to the first or second embodiment, the wired power-source line 31 or 41 may be used as, for example, the VDD wired power-source line or the VSS wired power-source line (cathode line) illustrated in FIG. 12.

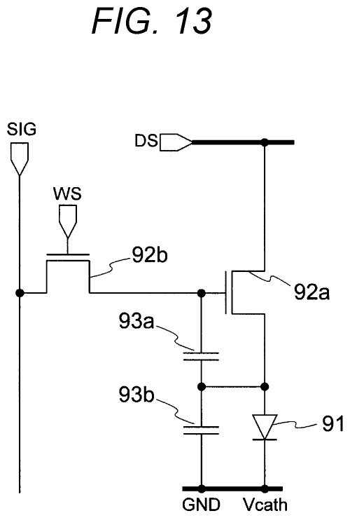

FIG. 13 is a circuit diagram illustrating the configuration of a displaying device according to the seventh embodiment.

Each pixel 11 according to the present embodiment has, for example, a circuit configuration illustrated in FIG. 13, and includes an organic EL element 91, two transistors 92a to 92b, and two capacitors 93a to 93b. The functions of the organic EL element 91, the transistors 92a to 92b, and the capacitors 93a to 93b according to the present embodiment are substantially similar to the functions of the organic EL element 21, the transistors 22a to 22d, and the capacitors 23a to 23b according to the first embodiment.

FIG. 13 illustrates a signal line SIG, a scan line WS, a drive line DS, a ground (GND) wired power-source line, and a cathode line that supplies a cathode electric potential Vcath to the organic EL element 91. The signal line SIG supplies signals to the pixel 11 illustrated in FIG. 13. The scan line WS is connected to a gate terminal of the transistor 92b. The drive line DS is connected to the transistor 92a. The GND wired power-source line is connected to, for example, the capacitor 93b.

In a case where the circuit configuration of the pixels 11 according to the present embodiment is applied to the first or second embodiment, the wired power-source line 31 or 41 may be used as, for example, the GND wired power-source line illustrated in FIG. 13.

As described above, the wired power-source lines 31 and 41 according to the first and second embodiments can be used as the various wired power-source lines.

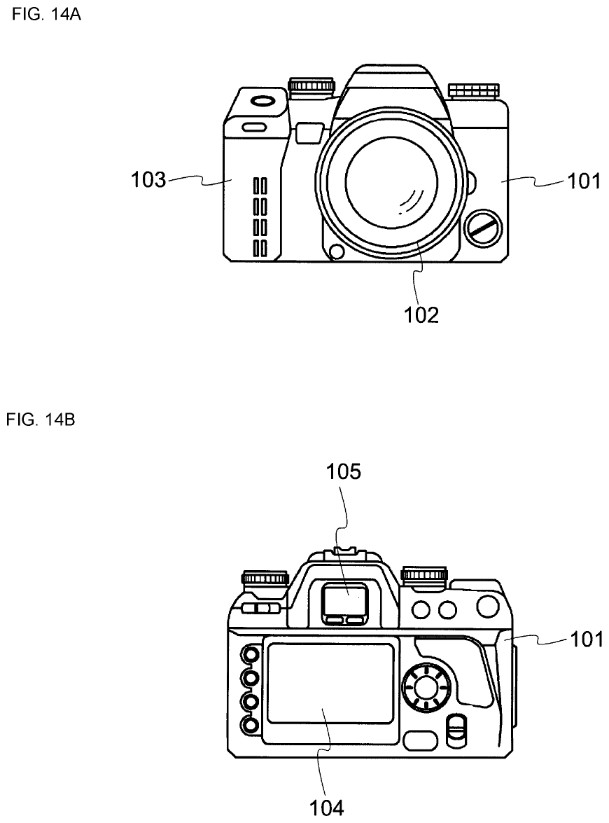

Note that the displaying devices according to the first to seventh embodiments can be applied to, for example, electronic equipment according to an eighth or ninth embodiment. Hereinafter, the electronic equipment according to the eighth and ninth embodiments will be described with reference to FIGS. 14 and 5.

### Eighth Embodiment

FIG. 14 is an exterior view illustrating the structure of electronic equipment according to the eighth embodiment.

The electronic equipment according to the present embodiment is portable electronic equipment, and is, for example, a camera including the displaying device according to any one of the first to seventh embodiments. A of FIG. 14 is a front view illustrating the camera according to the present embodiment. B of FIG. 14 is a rear view illustrating the camera according to the present embodiment. The camera according to the present embodiment is a digital still camera of an interchangeable-lens single-lens reflex type.

The camera according to the present embodiment includes an imaging-lens unit 102 of an interchangeable type on the right side of the front of a main camera body 101, and a grip 103, where the imaging person grips, on the left side of the front of the main camera body 101 (A of FIG. 14).

The camera according to the present embodiment also includes a monitor 104 in the back of the main camera body 101, and an electronic viewfinder (eyepiece window) 105 over the monitor 104 (B of FIG. 14). The imaging person looks through the electronic viewfinder 105 to visually recognize a light image of a subject guided from the imaging-lens unit 102, and decide the composition. In the present embodiment, the displaying device according to any one of the first to seventh embodiments is applied to the electronic viewfinder 105.

It is thought that in general, the downsizing of a displaying device is much needed for portable electronic equipment including a displaying device. For example, the electronic viewfinder 105 according to the present embodiment is wanted to be downsized to smaller than the main camera body 101, and furthermore is wanted to be downsized to smaller than the monitor 104. On the other hand, according to the first to seventh embodiments, the displaying panel P is downsized to downsize the displaying device. Therefore, according to the present embodiment, the displaying device according to any one of the first to seventh embodiments is applied to the electronic viewfinder 105 to downsize the electronic viewfinder 105.

### Ninth Embodiment

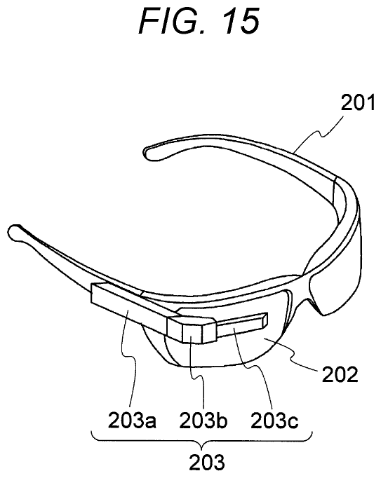

FIG. 15 is an exterior view illustrating the structure of electronic equipment according to the ninth embodiment.

The electronic equipment according to the present embodiment is wearable electronic equipment, and is, for example, glasses including the displaying device according to any one of the first to seventh embodiments. FIG. 15 is a perspective view illustrating the glasses according to the present embodiment.

The glasses according to the present embodiment include a main glasses body (frame) 201, two lenses 202, and a head-mounted display 203. The head-mounted display 203 according to the present embodiment has a head-mounted display configuration of a transparent type including a main body 203a, an arm 203b, and a lens barrel 203c.

The main body 203a is connected to the arm 203b and the main glasses body 201. Specifically, one end of the main body 203a is attached to the arm 203b, and the other end of the main body 203a is coupled to the main glasses body 201 through a connection member not illustrated. The main body 203a incorporates a control unit (control board) for controlling operations of the head-mounted display 203, and a displaying unit for displaying images and the like. Note that the main body 203a may be directly worn on the head of a human body.

The arm 203b couples the main body 203a to the lens barrel 203c to support the lens barrel 203c relative to the main body 203a. Specifically, the arm 203b is joined to an end of the main body 203a and an end of the lens barrel 203c to fix the lens barrel 203c relative to the main body 203a. The arm 203b incorporates a signal line for communicating data regarding images supplied to the lens barrel 203c from the main body 203a.

The lens barrel 203c emits image light supplied from the main body 203a through the arm 203b, toward the lens 202. The image light passes through the lens 202, and is projected toward an eye of a user who wears the glasses according to the present embodiment. In the present embodiment, the displaying device according to any one of the first to seventh embodiments is applied to the displaying unit in the main body 203a.

It is thought that in general, the downsizing of a displaying device is much needed for wearable electronic equipment including a displaying device. For example, the displaying unit in the main body 203a according to the present embodiment is wanted to be downsized to smaller than the main body 203a. On the other hand, according to the first to seventh embodiments, the displaying panel P is downsized to downsize the displaying device. Therefore, according to the present embodiment, the displaying device according to any one of the first to seventh embodiments is applied to the displaying unit in the main body 203a to downsize the displaying unit in the main body 203a.

Note that the displaying device, that is to say, the displaying unit in the main body 203a, is arranged, for example, such that the X-direction in FIGS. 3 and 7 is parallel to a lengthways direction of the main body 203a. That is to say, the displaying device is arranged such that sides, in the X-direction, of the displaying panel P are located left and right, and sides, in the Y-direction, of the displaying panel P are located up and down. In this case, it is preferable that the width, in the Y-direction, of the displaying panel P is short. The reason is that the width, in an up-down direction, of the main body 203a is short. Therefore, in a case where the displaying device according to any one of the first to seventh embodiments is applied to the displaying unit in the main body 203a, adopting the displaying device illustrated in FIG. 3 is preferable to adopting the displaying device illustrated in FIG. 7. The reason is that the width W1, in the Y-direction, of the displaying panel P is shortened for the displaying device illustrated in FIG. 3.

Although the embodiments of the present disclosure are described above, these embodiments may be variously modified to be implemented without departing from the gist of the present disclosure. For example, two or more of the embodiments may be combined to be implemented.

Note that the present disclosure can be configured as follows:

(1)

A displaying device including:

a pixel array area that includes a plurality of pixels;

a peripheral circuit provided outside the pixel array area;

a printed circuit provided outside the pixel array area; and

a wired power-source line that supplies a power source voltage to the peripheral circuit from the printed circuit through the pixel array area.

(2)

The displaying device according to (1), in which the wired power-source line supplies the power source voltage to the pixels and the peripheral circuit.

(3)

The displaying device according to (1), further including: a plurality of scan lines that extends in a first direction in the pixel array area;

a plurality of signal lines that extends in a second direction in the pixel array area;

a plurality of first wired power-source lines that extends in the first direction in the pixel array area; and

a plurality of second wired power-source lines that extends in the second direction in the pixel array area,

in which the wired power-source line that supplies the power source voltage to the peripheral circuit from the printed circuit includes the first wired power-source lines, the second wired power-source lines, or both the first and second wired power-source lines.

(4)

The displaying device according to (3), in which in a case where the wired power-source line that supplies the power source voltage to the peripheral circuit from the printed circuit includes the first wired power-source lines, a width of the first wired power-source lines is thicker than a width of the second wired power-source lines.

(5)

The displaying device according to (3), in which in a case where the wired power-source line that supplies the power source voltage to the peripheral circuit from the printed circuit includes the second wired power-source lines, a width of the second wired power-source lines is thicker than a width of the first wired power-source lines.

(6)

The displaying device according to (3), in which the pixels are supplied with a power source voltage from the first and second wired power-source lines.

(7)

The displaying device according to (3),

in which each of the pixels includes N (N is an integer equal to or larger than two) subpixels, and

the N subpixels are supplied with a power source voltage from N of the second wired power-source lines.

(8)

The displaying device according to (7), in which a width of the first wired power-source lines is N times a width of the second wired power-source lines.

(9)

The displaying device according to (1), further including:

a plurality of scan lines that extends in a first direction in the pixel array area; and

a plurality of signal lines that extends in a second direction in the pixel array area,

in which the printed circuit is provided in the first direction of the pixel array area.

(10)

The displaying device according to (9), in which the wired power-source line extends in the first direction in the pixel array area.

(11)

The displaying device according to (9), in which the peripheral circuit includes a writing and scanning unit electrically connected to the scan lines, and the writing and scanning unit is supplied with the power source voltage from the wired power-source line.

(12)

The displaying device according to (11), in which the writing and scanning unit and the printed circuit are provided on opposite sides of the pixel array area.

(13)

The displaying device according to (11),

in which the peripheral circuit further includes a signal output unit electrically connected to the signal lines, and

the signal output unit is supplied with a power source voltage from another wired power-source line different from the wired power-source line.

(14)

The displaying device according to (1), further including:

a plurality of scan lines that extends in a first direction in the pixel array area; and

a plurality of signal lines that extends in a second direction in the pixel array area,

in which the printed circuit is provided in the second direction of the pixel array area.

(15)

The displaying device according to (14), in which the wired power-source line extends in the second direction in the pixel array area.

(16)

The displaying device according to (14),

in which the peripheral circuit includes a signal output unit electrically connected to the signal lines, and

the signal output unit is supplied with the power source voltage from the wired power-source line.

(17)

The displaying device according to (16), in which the signal output unit and the printed circuit are provided on opposite sides of the pixel array area.

(18)

The displaying device according to (16),

in which the peripheral circuit further includes a writing and scanning unit electrically connected to the scan lines, and

the writing and scanning unit is supplied with a power source voltage from another wired power-source line different from the wired power-source line.

(19)

The displaying device according to (1), in which the displaying device is part of portable or wearable electronic equipment.

(20)

The displaying device according to (19), in which the electronic equipment includes a camera or glasses that include the displaying device.

### REFERENCE SIGNS LIST

1 Pixel array area
2 Signal output unit
3 Writing and scanning unit
4 First driving and scanning unit
5 Second driving and scanning unit
6 FPC
11 Pixel
11a, 11b, 11c Subpixel
12 Signal line (SIG line)
13 Scan line (WS line)
14 First drive line (DS line)
15 Second drive line (AZ line)
21 Organic EL element
22a to 22d Transistor
23a to 23b Capacitor
31, 31a to 31d Wired power-source line
32 Wired power-source line
33, 33a to 33d Wired power-source line
34 Wired power-source line
35 Wired power-source line
41, 41a to 41d Wired power-source line
42 Wired power-source line
43, 43a to 43d Wired power-source line
44 Wired power-source line
45 Wired power-source line
51 Organic EL element
52a to 52e Transistor
53 Capacitor
61 Organic EL element
62a to 62d Transistor
63 Capacitor
71 Organic EL element
72a to 72f Transistor
73a to 73c Capacitor
81 Organic EL element
82a to 82i Transistor
83a to 83b Capacitor
91 Organic EL element
92a to 92b Transistor
93a to 93b Capacitor
101 Main camera body
102 Imaging-lens unit
103 Grip
104 Monitor
105 Electronic viewfinder
201 Main glasses body
202 Lens
203 Head-mounted display
203a Main body
203b Arm
203c Lens barrel

1. A displaying device comprising:
a pixel array area that includes a plurality of pixels;
a peripheral circuit provided outside the pixel array area;
a printed circuit provided outside the pixel array area; and
a wired power-source line that supplies a power source voltage to the peripheral circuit from the printed circuit through the pixel array area.

2. The displaying device according to claim 1, wherein the wired power-source line supplies the power source voltage to the pixels and the peripheral circuit.

3. The displaying device according to claim 1, further comprising:
a plurality of scan lines that extends in a first direction in the pixel array area;
a plurality of signal lines that extends in a second direction in the pixel array area;
a plurality of first wired power-source lines that extends in the first direction in the pixel array area; and
a plurality of second wired power-source lines that extends in the second direction in the pixel array area,
wherein the wired power-source line that supplies the power source voltage to the peripheral circuit from the printed circuit includes the first wired power-source lines, the second wired power-source lines, or both the first and second wired power-source lines.

4. The displaying device according to claim 3, wherein in a case where the wired power-source line that supplies the power source voltage to the peripheral circuit from the printed circuit includes the first wired power-source lines, a width of the first wired power-source lines is thicker than a width of the second wired power-source lines.

5. The displaying device according to claim 3, wherein in a case where the wired power-source line that supplies the power source voltage to the peripheral circuit from the printed circuit includes the second wired power-source lines, a width of the second wired power-source lines is thicker than a width of the first wired power-source lines.

6. The displaying device according to claim 3, wherein the pixels are supplied with a power source voltage from the first and second wired power-source lines.

7. The displaying device according to claim 3,
wherein each of the pixels includes N (N is an integer equal to or larger than two) subpixels, and
the N subpixels are supplied with a power source voltage from N of the second wired power-source lines.

8. The displaying device according to claim 7, wherein a width of the first wired power-source lines is N times a width of the second wired power-source lines.

9. The displaying device according to claim 1, further comprising:
a plurality of scan lines that extends in a first direction in the pixel array area; and
a plurality of signal lines that extends in a second direction in the pixel array area,
wherein the printed circuit is provided in the first direction of the pixel array area.

10. The displaying device according to claim 9, wherein the wired power-source line extends in the first direction in the pixel array area.

11. The displaying device according to claim 9,
wherein the peripheral circuit includes a writing and scanning unit electrically connected to the scan lines, and
the writing and scanning unit is supplied with the power source voltage from the wired power-source line.

12. The displaying device according to claim 11, wherein the writing and scanning unit and the printed circuit are provided on opposite sides of the pixel array area.

13. The displaying device according to claim 11,
wherein the peripheral circuit further includes a signal output unit electrically connected to the signal lines, and
the signal output unit is supplied with a power source voltage from another wired power-source line different from the wired power-source line.

14. The displaying device according to claim 1, further comprising:
a plurality of scan lines that extends in a first direction in the pixel array area; and
a plurality of signal lines that extends in a second direction in the pixel array area,
wherein the printed circuit is provided in the second direction of the pixel array area.

15. The displaying device according to claim 14, wherein the wired power-source line extends in the second direction in the pixel array area.

16. The displaying device according to claim 14,
wherein the peripheral circuit includes a signal output unit electrically connected to the signal lines, and
the signal output unit is supplied with the power source voltage from the wired power-source line.

17. The displaying device according to claim 16, wherein the signal output unit and the printed circuit are provided on opposite sides of the pixel array area.

18. The displaying device according to claim 16,
wherein the peripheral circuit further includes a writing and scanning unit electrically connected to the scan lines, and
the writing and scanning unit is supplied with a power source voltage from another wired power-source line different from the wired power-source line.

19. The displaying device according to claim 1, wherein the displaying device is part of portable or wearable electronic equipment.

20. The displaying device according to claim 19, wherein the electronic equipment includes a camera or glasses that include the displaying device.
